(19) United States
(12) Patent Application Publication
(10) Pub. No.: US 2012/0196389 A1
(43) Pub. Date: Aug. 2, 2012

(54) DEFECT INSPECTION METHOD AND MANUFACTURING METHOD OF SEMICONDUCTOR DEVICE

(76) Inventor: Yasuo MATSUOKA, Kanagawa (JP)

(21) Appl. No.: 13/329,718

(22) Filed: Dec. 19, 2011

(30) Foreign Application Priority Data
Feb. 2, 2011 (JP) 2011-020375

(51) Int. Cl. H01L 21/66

(52) U.S. Cl. 438/17; 257/E21.531

(57) ABSTRACT

According to one embodiment, electrolytic solution is selectively jetted onto an imprint pattern, the electrolytic solution is jetted onto each shot or part of an area in a shot, an electrode is separated for each shot, and the electrode is switched according to a shot to be an inspection target.

### CROSS-REFERENCE TO RELATED APPLICATIONS

This application is based upon and claims the benefit of priority from Japanese Patent Application No. 2011-20375, filed on Feb. 2, 2011; the entire contents of which are incorporated herein by reference.

### FIELD

Embodiments described herein relate generally to a defect inspection method and a manufacturing method of a semiconductor device.

### BACKGROUND

In a manufacturing process of semiconductor devices, a nanoimprint exposure method attracts attention, in which a mold of a master is transferred onto a transfer target substrate. The nanoimprint method is a method in which a mold of a master (template), on which a pattern to be transferred is formed, is pressed against a resist layer, which is applied to a substrate and is formed of an imprint material, and the resist layer is cured thereby transferring the pattern onto the resist layer.

In this nanoimprint pattern forming method, imprinting is performed by bringing a template and a wafer into close contact with each other, so that breakage or defect of the template occurs accidentally. If the imprint process is continued while leaving such damage or defect of the template, a large number of defective products are generated, so that it is desired to detect damage or defect of the template early.

### BRIEF DESCRIPTION OF THE DRAWINGS

FIGS. 1A to 1E are cross-sectional views illustrating a defect inspection method when there is no defect of a template according to a first embodiment;

FIGS. 2A to 2D are cross-sectional views illustrating a defect inspection method when there is a defect of a template according to the first embodiment;

FIG. 3 is a flowchart illustrating the defect inspection method according to the first embodiment;

FIG. 4 is a cross-sectional view illustrating a defect inspection method according to a second embodiment;

FIG. 5 is a plan view illustrating the defect inspection method according to the second embodiment;

FIG. 6 is a plan view illustrating a relationship between a shot position and current in the defect inspection method according to the second embodiment;

FIG. 7 is a flowchart illustrating the defect inspection method according to the second embodiment;

FIG. 8 is a cross-sectional view illustrating a defect inspection method according to a third embodiment;

FIG. 9 is a plan view illustrating the defect inspection method according to the third embodiment;

FIG. 10 is a plan view illustrating a schematic configuration of a defect inspection apparatus according to a fourth embodiment;

FIG. 11 is a cross-sectional view illustrating a defect inspection method according to a fifth embodiment;

FIG. 12 is a cross-sectional view illustrating a defect inspection method according to a sixth embodiment; and

FIG. 13 is a cross-sectional view illustrating a defect inspection method according to a seventh embodiment.

### DETAILED DESCRIPTION

In general, according to a defect inspection method of embodiments, a conductive layer is formed on a base layer. Next, an imprint pattern is formed on the conductive layer. Next, an electrolytic solution is brought into contact with the imprint pattern. Next, an electrode is brought into contact with the electrolytic solution. Next, voltage is applied between the conductive layer and the electrode. Next, current flowing between the conductive layer and the electrode when the voltage is applied between the conductive layer and the electrode is measured. Next, the presence or absence of a defect of the imprint pattern is determined based on a measuring result of the current.

A defect inspection method according to the embodiments will be explained below with reference to the drawings. The present invention is not limited to these embodiments.

(First Embodiment)

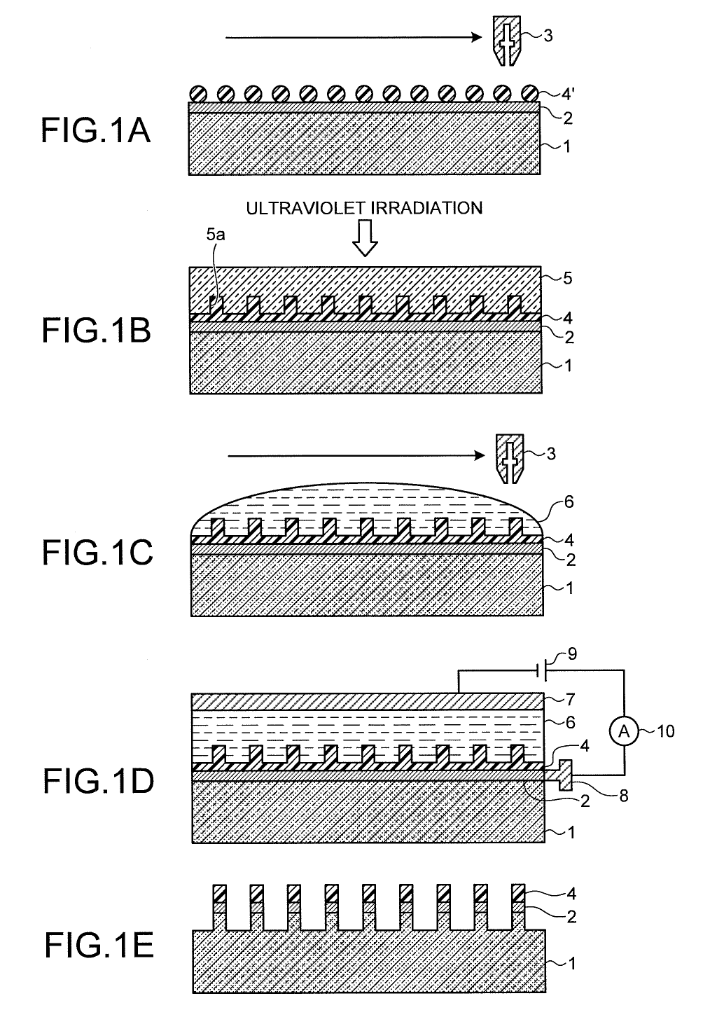

FIGS. 1A to 1E are cross-sectional views illustrating a schematic configuration of a defect inspection method according to the first embodiment.

In FIG. 1A, a conductive layer 2 is formed on a base layer 1. As the base layer 1, for example, a semiconductor substrate can be used. Alternatively, the base layer 1 may be a dielectric layer on a semiconductor substrate or a conductive layer on a dielectric layer. As the conductive layer 2, for example, it is possible to use a film in which conductor is mixed in an adhesion layer that increases the adhesion strength of a resist pattern. As this adhesion layer, for example, an inter-layer dielectric film, such as a low-k (low-dielectric constant) film or an organic film, can be used. As the conductor to be mixed in the adhesion layer, for example, metal fine particles can be used. Moreover, as a forming method of the conductive layer 2, for example, spin coating may be used. Alternatively, the conductive layer 2 may be formed by a method such as sputtering of metal as long as adhesion with the base layer 1 can be ensured.

Next, an imprint material 4′ is jetted onto the conductive layer 2 via a nozzle 3 by using a method such as an ink jet method. As the imprint material 4′, for example, ultraviolet curable resist can be used. Moreover, the imprint material 4′ may be formed of insulator.

Next, as shown in FIG. 1B, an imprint pattern 4 is formed on the conductive layer 2 by pressing a template 5 against the imprint material 4′. The template 5 is, for example, formed of quartz. A recess portion 5a corresponding to the imprint pattern 4 is formed on the template 5. Then, when the template 5 is pressed against the imprint material 4′, the imprint material 4′ is drawn into the recess portion 5a by capillary action and therefore the imprint pattern 4 corresponding to the shape of the recess portion 5a is formed.

Then, the imprint pattern 4 is cured by irradiating the imprint pattern 4 with ultraviolet rays through the template 5 in a state where the template 5 is pressed against the imprint pattern 4.

In the example of FIG. 1B, ultraviolet curable resist may be used as the imprint material 4′ for making the imprint pattern 4 to cure, however, thermosetting resist may be used.

Next, as shown in FIG. 1C, after removing the template 5 from the imprint pattern 4, electrolytic solution 6 is jetted onto the imprint pattern 4 via the nozzle 3 by using a method such as an ink jet method. As the electrolytic solution 6, for example, sodium hydroxide solution may be used.

Next, as shown in FIG. 1D, an electrode 7 is brought into contact with the electrolytic solution 6 and an electrode 8 is brought into contact with the conductive layer 2. The electrodes 7 and 8 may be a probe electrode or a plate electrode. Moreover, for the electrodes 7 and 8, metal such as Cu and Al can be used.

Then, voltage is applied between the electrodes 7 and 8 via a power supply 9 and current that flows between the electrodes 7 and 8 at that time is measured by an ammeter 10. At this time, because the imprint pattern 4 is formed of insulator, when there is no defect in the imprint pattern 4, current does not flow between the electrodes 7 and 8.

Then, the measured value of the current measured by the ammeter 10 is compared with a threshold, and when the measured value is equal to or lower than the threshold, it is determined that there is no defect in the imprint pattern 4.

Next, as shown in FIG. 1E, the electrolytic solution 6 and the electrode 7 are removed from over the imprint pattern 4 and the electrode 8 is removed from the conductive layer 2. As a method of removing the electrolytic solution 6 from over the imprint pattern 4, the electrolytic solution 6 may be dried by natural drying or a blower process may be performed. Moreover, after removing the electrolytic solution 6 from over the imprint pattern 4, the surface of the imprint pattern 4 may be cleaned.

Then, when it is determined that there is no defect of the imprint pattern 4, the base layer 1 is processed via the imprint pattern 4. As the process performed on the base layer 1, ion implantation may be performed on the base layer 1 via the imprint pattern 4 or the base layer 1 may be etched with the imprint pattern 4 as a mask. Thereafter, the conductive layer 2 and the imprint pattern 4 remaining on the base layer 1 are removed.

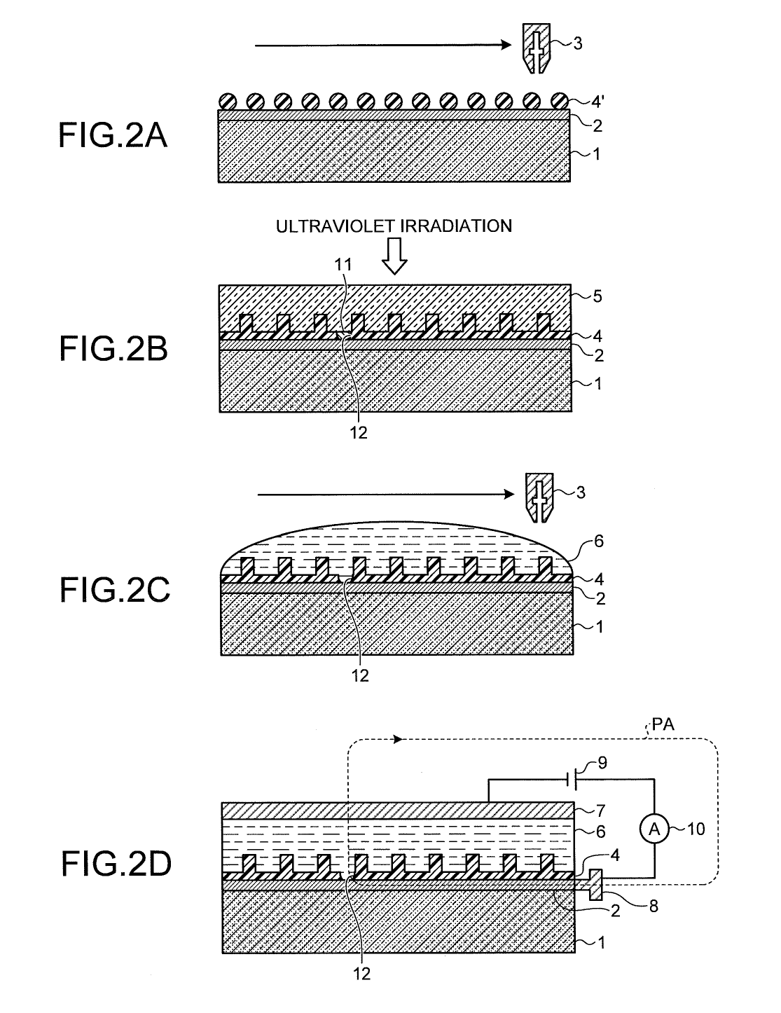

FIGS. 2A to 2D are cross-sectional views illustrating a defect inspection method when there is a defect of a template according to the first embodiment.

In FIG. 2A, in the similar manner to FIG. 1A, after forming the conductive layer 2 on the base layer 1, the imprint material 4′ is jetted onto the conductive layer 2 via the nozzle 3.

Next, as shown in FIG. 2B, the imprint pattern 4 is formed on the conductive layer 2 by pressing the template 5 against the imprint material 4′. At this time, when foreign matter 11 such as dust adheres to the surface of the template 5, the foreign matter 11 is also transferred onto the imprint pattern 4, so that a defect 12 is generated in the imprint pattern 4.

The cause of generation of the defect 12 in the imprint pattern 4, for example, includes poor filling (dust or resist stripping at the time of releasing) of resist, air bubble, microbubble, ink jet bubble, clogging of the template recess portion by foreign matter, and foreign matter on a wafer substrate.

Next, as shown in FIG. 2C, after removing the template 5 from the imprint pattern 4, the electrolytic solution 6 is jetted onto the imprint pattern 4 via the nozzle 3. At this time, the electrolytic solution 6 penetrates into the defect 12 and comes into contact with the conductive layer 2.

Next, as shown in FIG. 2D, the electrode 7 is brought into contact with the electrolytic solution 6 and the electrode 8 is brought into contact with the conductive layer 2. Then, voltage is applied between the electrodes 7 and 8 via the power supply 9 and current that flows between the electrodes 7 and 8 at that time is measured by the ammeter 10. At this time, because the electrolytic solution 6 is in contact with the conductive layer 2 through the defect 12, current flows between the electrodes 7 and 8 through a current path PA. Then, the measured value of the current measured by the ammeter 10 is compared with a threshold, and when the measured value exceeds the threshold, it is determined that there is a defect in the imprint pattern 4.

When it is determined that there is a defect in the imprint pattern 4, the subsequent processes are stopped, so that a large number of defective products can be prevented from being generated.

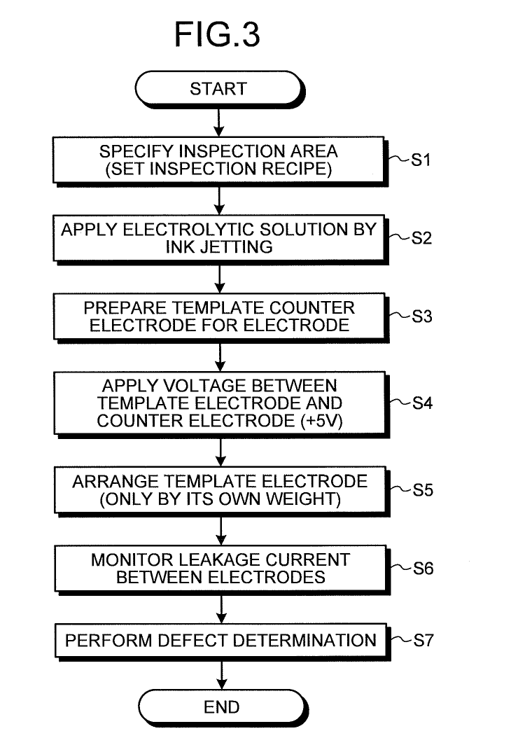

FIG. 3 is a flowchart illustrating the defect inspection method according to the first embodiment.

In FIG. 3, an inspection area on a wafer on which an imprint pattern is formed is specified (S1). The inspection area can be set in an inspection recipe.

Next, electrolytic solution is applied to the inspection area by an ink jet method (S2). In the ink jet method, the inspection area can be specified for each area of one droplet and, for example, the area of one droplet can be 20 μmΦ).

Next, a template counter electrode for electrode is prepared (S3) and voltage is applied between the template electrode and the counter electrode (S4).

Next, the template electrode is arranged on the electrolytic solution (S5) and current between the template electrode and the counter electrode is monitored (S6). The template electrode may be arranged on the electrolytic solution only by its own weight. The presence or absence of a defect of the imprint pattern is determined based on the monitor result of the current between the template electrode and the counter electrode (S7).

(Second Embodiment)

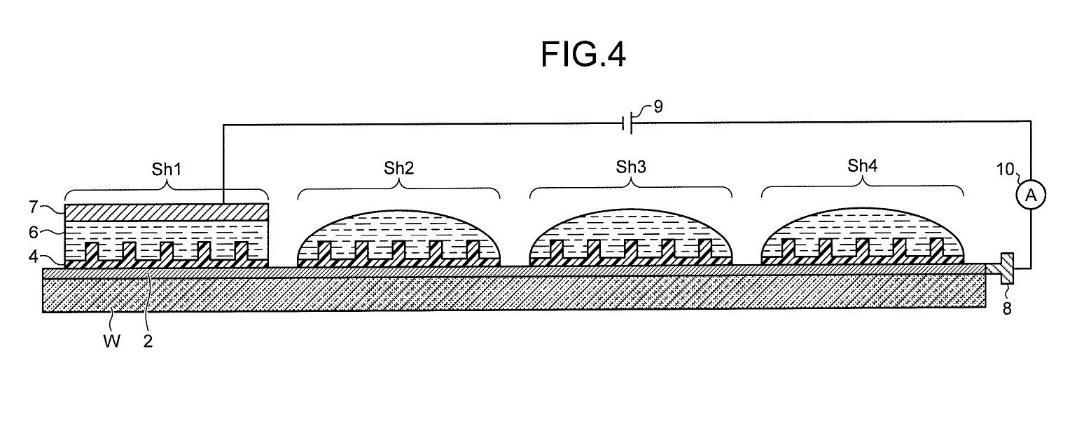

FIG. 4 is a cross-sectional view illustrating a defect inspection method according to the second embodiment.

In FIG. 4, the imprint pattern 4 is formed on a wafer W via the conductive layer 2 in each of shot areas Sh1 to Sh4. Then, the electrolytic solution 6 is applied to each of the shot areas Sh1 to Sh4 by an ink jet method.

Then, the electrode 7 is brought into contact with the electrolytic solution 6 while moving the electrode 7 for each of the shot areas Sh1 to Sh4 to measure current flowing between the electrodes 7 and 8 by the ammeter 10 for each of the shot areas Sh1 to Sh4. Then, the measured value of the current measured by the ammeter 10 is compared with a threshold for each of the shot areas Sh1 to Sh4 to determine the presence or absence of a defect of the imprint pattern 4 for each of the shot areas Sh1 to Sh4.

Consequently, the presence or absence of a defect of the imprint pattern 4 can be determined for each of the shot areas Sh1 to Sh4, enabling to make it easy to determine the cause of generation of a defect of the imprint pattern 4.

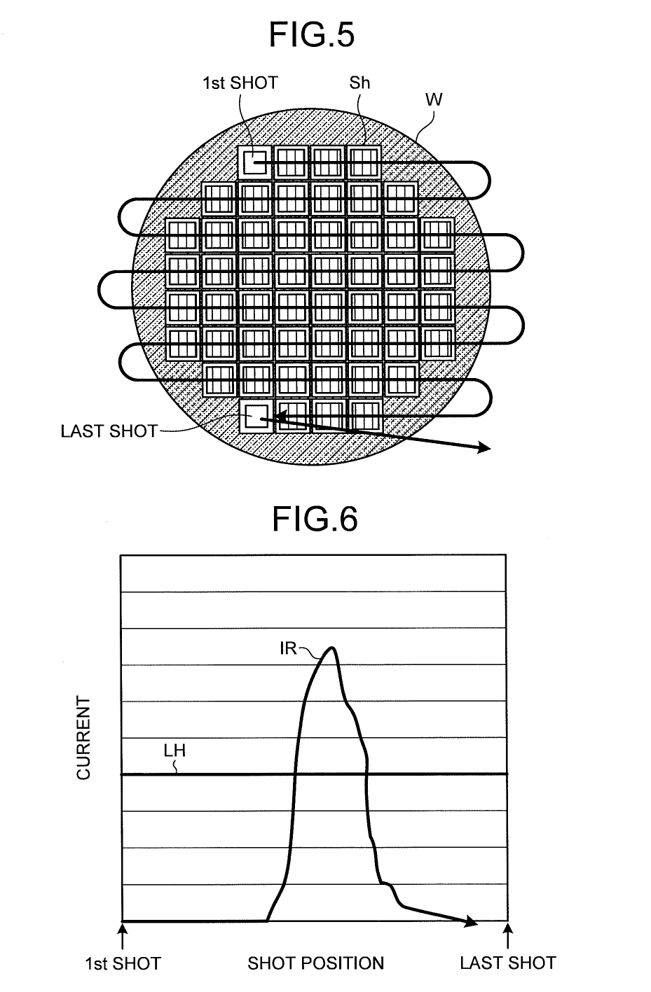

FIG. 5 is a plan view illustrating the defect inspection method according to the second embodiment.

In FIG. 5, the wafer W is partitioned into shot areas Sh. After applying electrolytic solution to each shot area Sh by an ink jet method, current leakage is monitored for each shot area Sh, so that the presence or absence of a defect can be determined for each shot area Sh.

FIG. 6 is a plan view illustrating a relationship between a shot position and current in the defect inspection method according to the second embodiment.

In FIG. 6, a current leakage amount IR is compared with a threshold LH for each shot area Sh. The shot area Sh, in which the current leakage amount IR is equal to or less than the threshold LH, is determined to have no defect and the shot area Sh, in which the current leakage amount IR exceeds than the threshold LH, is determined to have a defect.

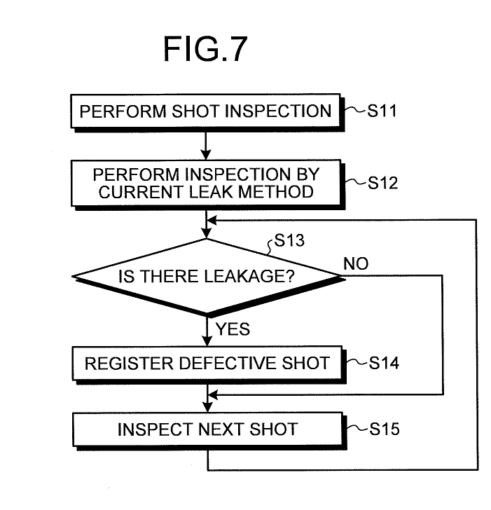

FIG. 7 is a flowchart illustrating the defect inspection method according to the second embodiment.

In FIG. 7, when the shot inspection is performed (S11), the current leakage is monitored for each shot area Sh (S12). When the current leakage amount exceeds the threshold LH (S13), the shot area Sh is registered as a defective shot (S14) and then, the next shot area Sh is inspected (S15).

(Third Embodiment)

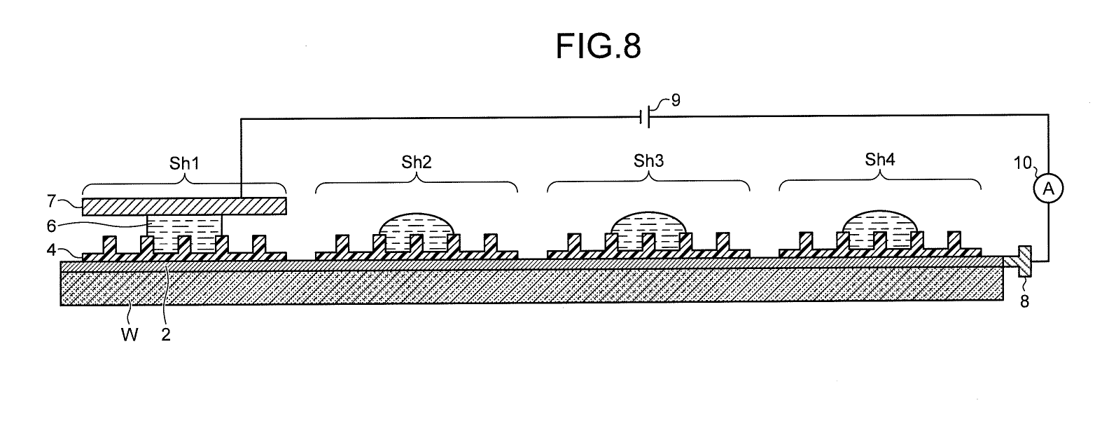

FIG. 8 is a cross-sectional view illustrating a defect inspection method according to the third embodiment.

In FIG. 8, the imprint pattern 4 is formed on the wafer W via the conductive layer 2 in each of the shot areas Sh1 to Sh4. Then, the electrolytic solution 6 is applied to each of the shot areas Sh1 to Sh4 by an ink jet method. At this time, the electrolytic solution 6 is applied selectively to part of each of the shot areas Sh1 to Sh4. For example, the electrolytic solution 6 can be applied separately to a cell region and a peripheral circuit region in a NAND-type flash memory.

Then, the electrode 7 is brought into contact with the electrolytic solution 6 while moving the electrode 7 for each of the shot areas Sh1 to Sh4 to measure current flowing between the electrodes 7 and 8 by the ammeter 10 for each of the shot areas Sh1 to Sh4. Then, the measured value of the current measured by the ammeter 10 is compared with a threshold for each of the shot areas Sh1 to Sh4 to determine the presence or absence of a defect in a specific portion of the imprint pattern 4 for each of the shot areas Sh1 to Sh4.

Consequently, the presence or absence of a defect of the imprint patterns 4 can be determined for each circuit function, enabling to make it easy to determine the cause of generation of a defect of the imprint pattern 4.

For example, a position in the imprint pattern 4, at which a defect is generated, can be narrowed by performing the defect inspection on the imprint patterns 4 by the method in FIG. 4 and narrowing the area to apply the electrolytic solution 6 targeting the shot area determined to have a defect in the defect inspection among the shot areas Sh1 to Sh4.

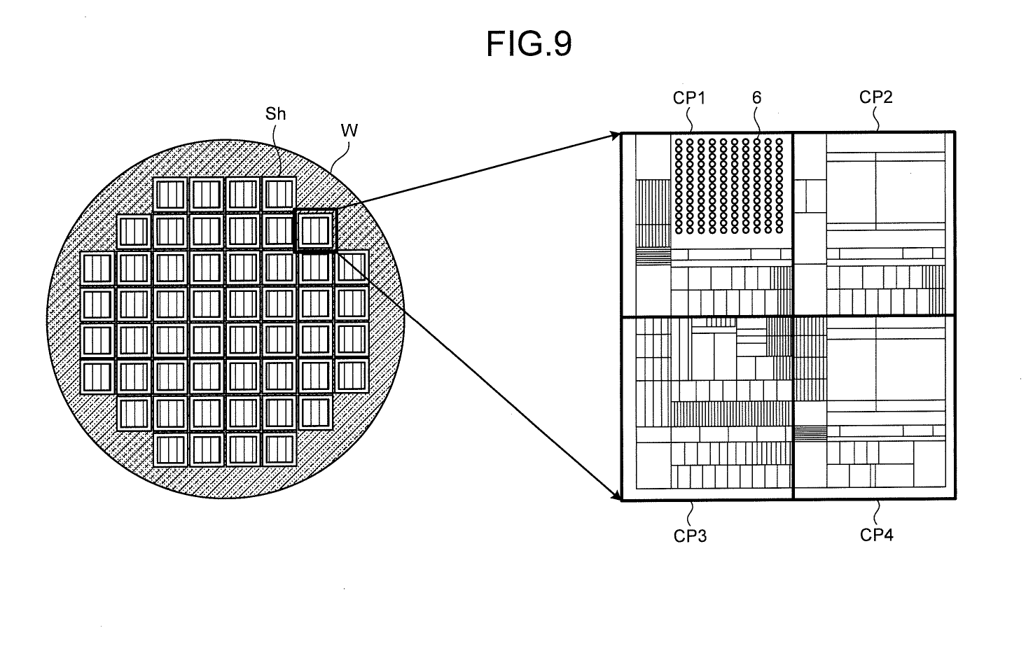

FIG. 9 is a plan view illustrating the defect inspection method according to the third embodiment.

In FIG. 9, the wafer W is partitioned into the shot areas Sh. Moreover, each shot area Sh is partitioned into chip areas CP1 to CP4. After applying the electrolytic solution 6 to only part of the chip area CP1 for each shot area Sh by an ink jet method, current leakage is monitored for each shot area Sh, so that the presence or absence of a defect can be determined for each specific portion in the shot area Sh.

(Fourth Embodiment)

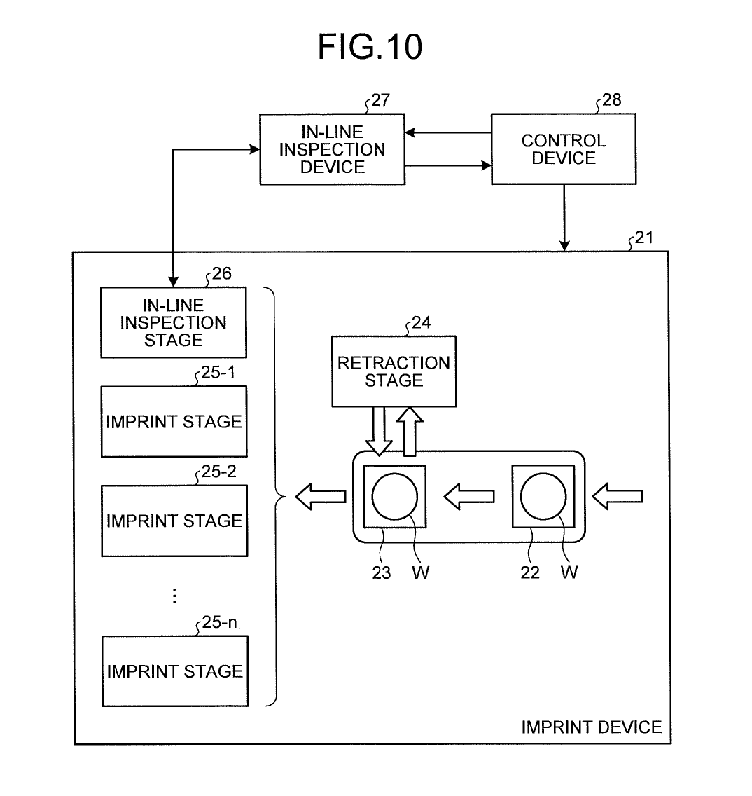

FIG. 10 is a plan view illustrating a schematic configuration of a defect inspection apparatus according to the fourth embodiment.

In FIG. 10, an imprint device 21 includes a wafer temperature controlling stage 22 in which temperature of the wafer W is controlled, a pre-alignment stage 23 in which the conveying position of the wafer W is adjusted, a retraction stage 24 in which the wafer W is temporarily retracted, n (n is an integer of two or larger) number of imprint stages 25-1 to 25-n on which the wafer W to be subjected to the imprint process is arranged, an in-line inspection stage 26 on which the wafer W to be subjected to the in-line inspection is arranged, an in-line inspection device 27 that performs the in-line inspection on the wafer W arranged on the in-line inspection stage 26, and a control device 28 that controls the imprint device 21 based on the in-line inspection result.

In each of the imprint stages 25-1 to 25-n, the nozzle 3 in FIG. 1A, the template 5 in FIG. 1B, and an ultraviolet irradiation device can be provided. In the in-line inspection stage 26, the nozzle 3, the electrodes 7 and 8, the power supply 9, and the ammeter 10 in FIG. 1D can be provided.

Then, the wafer W on which the conductive layer 2 is formed is conveyed to the wafer temperature controlling stage 22 to be subjected to temperature control and thereafter, the wafer W is conveyed to the pre-alignment stage 23. Then, the wafer W is conveyed to a free stage among the imprint stages 25-1 to 25-n via the pre-alignment stage 23 to be subjected to the imprint process, so that the imprint pattern 4 is formed on the conductive layer 2, and the wafer W is conveyed from a stage, in which the imprint process is finished, among the imprint stages 25-1 to 25-n to the in-line inspection stage 26. Then, the in-line inspection is performed in the in-line inspection stage 26 and current leakage in the imprint pattern 4 on the conductive layer 2 is monitored.

Then, the wafer W, on which the in-line inspection is performed, is conveyed out of the in-line inspection stage 26, and if the wafer W inhibits conveyance of the wafer W into the imprint stages 25-1 to 25-n, the wafer W is temporarily retracted to the retraction stage 24 via the pre-alignment stage 23.

Moreover, in the in-line inspection device 27, the presence or absence of a defect of the imprint pattern 4 is determined based on the current leakage amount and the presence or absence of a defect is registered for each wafer W. Then, in the control device 28, a stage, in which the imprint process is performed on the wafer W having a defect, is specified from among the imprint stages 25-1 to 25-n and the use of the stage among the imprint stages 25-1 to 25-n is suspended.

Consequently, one in-line inspection stage 26 can be shared by a plurality of the imprint stages 25-1 to 25-n, so that the operating rate of the in-line inspection stage 26 can be improved and the in-line inspection can be performed while shortening the standby time after the imprint process. Thus, it is possible to reduce the risk of generating a large number of defective products in the mass production.

(Fifth Embodiment)

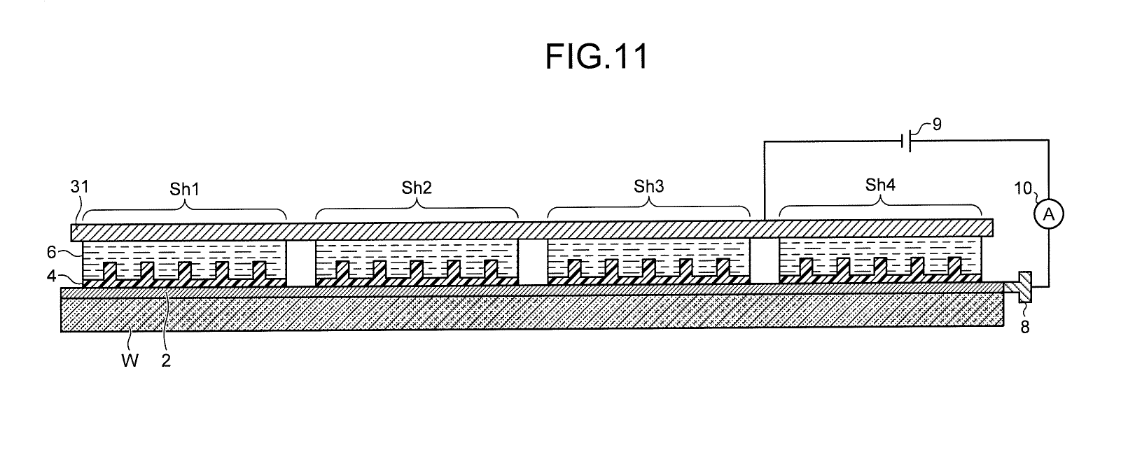

FIG. 11 is a cross-sectional view illustrating a defect inspection method according to the fifth embodiment.

In FIG. 11, in this defect inspection method, an electrode 31 is used instead of the electrode 7 in FIG. 4. Whereas the electrode 7 is brought into contact with the electrolytic solution in one shot area, the electrode 31 is brought into contact with all of the electrolytic solutions on the wafer W in a plurality of the shot areas Sh1 to Sh4 collectively. For example, in order to bring the electrode 31 into contact with all of the shot areas Sh1 to Sh4 on the wafer W collectively, the shape of the electrode 31 can be, for example, set to the shape similar to the wafer W.

Then, after applying the electrolytic solution 6 to each of the shot areas Sh1 to Sh4 by an ink jet method, the electrode 31 is brought into contact with all of the electrolytic solutions 6 in a plurality of the shot areas Sh1 to Sh4 collectively to measure current flowing between the electrodes 31 and 8 by the ammeter 10. Then, the measured value of the current measured by the ammeter 10 is compared with a threshold to determine the presence or absence of a defect of the imprint patterns 4 collectively for a plurality of the shot areas Sh1 to Sh4.

Consequently, the presence or absence of a defect of the imprint patterns 4 can be determined for a plurality of the shot areas Sh1 to Sh4 in one current measuring process, so that the time required for the defect inspection process can be shortened.

(Sixth Embodiment)

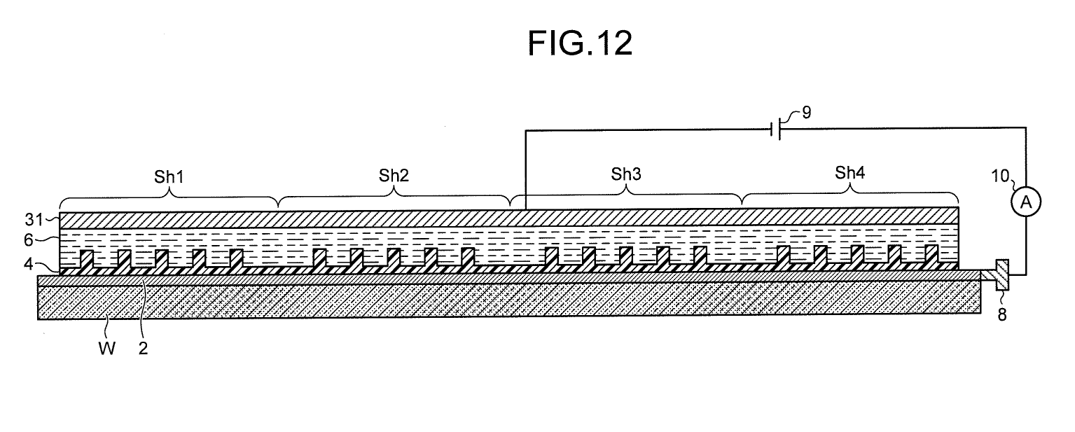

FIG. 12 is a cross-sectional view illustrating a defect inspection method according to the sixth embodiment.

Whereas the imprint pattern 4 is separated for each of the shot areas Sh1 to Sh4 in the defect inspection method in FIG. 11, in the defect inspection method in FIG. 12, the imprint pattern 4 is formed continuously over the shot areas Sh1 to Sh4 to prevent the conductive layer 2 from being exposed from the imprint pattern 4 between the shot areas Sh1 to Sh4.

After applying the electrolytic solution 6 continuously over the shot areas Sh1 to Sh4 by an ink jet method, the electrode 31 is brought into contact with the electrolytic solution 6 to measure current flowing between the electrodes 31 and 8 by the ammeter 10. Then, the measured value of the current measured by the ammeter 10 is compared with a threshold to determine the presence or absence of a defect of the imprint pattern 4 collectively for a plurality of the shot areas Sh1 to Sh4.

Consequently, the presence or absence of a defect of the imprint pattern 4 can be determined for a plurality of the shot areas Sh1 to Sh4 in one current measuring process without separating the electrolytic solution 6 for each of the shot areas Sh1 to Sh4, so that the time required for the defect inspection process can be shortened.

(Seventh Embodiment)

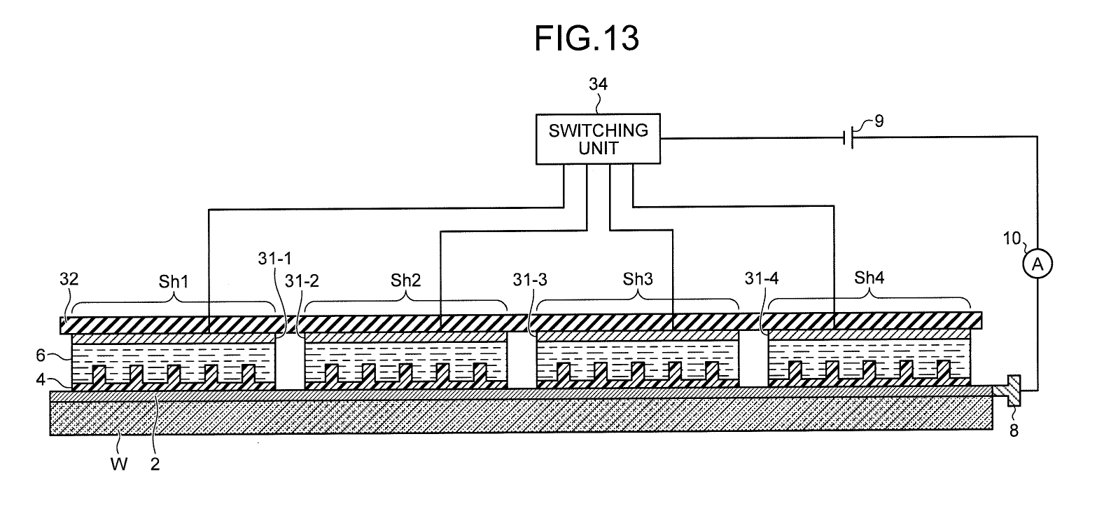

FIG. 13 is a cross-sectional view illustrating a defect inspection method according to the seventh embodiment.

In FIG. 13, in this defect inspection method, electrodes 31-1 to 31-4 are used instead of the electrode 31 in FIG. 11. The electrodes 31-1 to 31-4 are supported by a support substrate 32. As the support substrate 32, for example, insulator such as glass and resin can be used. As the electrodes 31-1 to 31-4, for example, a metal film such as Cu and Al can be used. Whereas the electrode 31 is brought into contact with all of a plurality of the shot areas Sh1 to Sh4 on the wafer W collectively, the electrodes 31-1 to 31-4 are brought into contact with the electrolytic solutions in a plurality of the shot areas Sh1 to Sh4, respectively. Moreover, in order to collectively bring the electrodes 31-1 to 31-4 into contact with a plurality of the shot areas Sh1 to Sh4 on the wafer W, respectively, the shape of the support substrate 32 can be, for example, set to the shape similar to the wafer W. The electrodes 31-1 to 31-4 are connected to the power supply 9 via a switching unit 34. The switching unit 34 can select one of the electrodes 31-1 to 31-4 and connect it to the power supply 9.

After applying the electrolytic solution 6 to each of the shot areas Sh1 to Sh4 by an ink jet method, the electrodes 31-1 to 31-4 are brought into contact with the electrolytic solutions 6 in the shot areas Sh1 to Sh4, respectively. Then, while sequentially switching between the electrodes 31-1 to 31-4 by the switching unit 34, current flowing between each of the electrodes 31-1 to 31-4 and the electrode 8 is measured by the ammeter 10. Then, the measured value of each current measured by the ammeter 10 is compared with a threshold to determine the presence or absence of a defect of the imprint pattern 4 for each of the shot areas Sh1 to Sh4.

Consequently, the presence or absence of a defect of the imprint pattern 4 can be determined for each of the shot areas Sh1 to Sh4 in a state where the positions of the electrodes 31-1 to 31-4 are fixed, enabling to make it easy to determine the cause of generation of a defect of the imprint pattern 4 while shortening the time required for a process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A defect inspection method comprising:
forming a conductive layer on a base layer;
forming an imprint pattern on the conductive layer;
bringing an electrolytic solution into contact with the imprint pattern;
bringing an electrode into contact with the electrolytic solution;
applying a voltage between the conductive layer and the electrode;
measuring a current flowing between the conductive layer and the electrode when the voltage is applied between the conductive layer and the electrode; and
determining presence or absence of a defect of the imprint pattern based on a measuring result of the current.

2. The defect inspection method according to claim 1, wherein the electrolytic solution is selectively jetted onto the imprint pattern.

3. The defect inspection method according to claim 2, wherein the electrolytic solution is jetted onto each shot or part of an area in a shot.

4. The defect inspection method according to claim 3, wherein the electrolytic solution is jetted by an ink jet method.

5. The defect inspection method according to claim 1, wherein
the electrode is separated for each shot, and
the electrode is switched according to a shot to be an inspection target.

6. The defect inspection method according to claim 1, wherein
the electrolytic solution is selectively jetted onto the imprint pattern,
the electrolytic solution is jetted onto each shot or part of an area in a shot,
the electrode is separated for each shot, and
the electrode is switched according to a shot to be an inspection target.

7. The defect inspection method according to claim 1, wherein
the forming the imprint pattern on the conductive layer includes
jetting an imprint material onto the conductive layer,
pressing a template, on which a recess portion corresponding to the imprint pattern is formed, against the imprint material, and
making the imprint material to cure while pressing the template against the imprint material.

8. The defect inspection method according to claim 7, wherein one in-line inspection stage is shared by a plurality of imprint stages.

9. The defect inspection method according to claim 1, wherein
the imprint pattern is formed separately for each shot area and the electrolytic solution is brought into contact with the imprint pattern separately for each shot area, and
the electrode is brought into contact with all of electrolytic solutions in a plurality of shot areas collectively.

10. The defect inspection method according to claim 1, wherein
the imprint pattern is formed continuously over a plurality of shot areas and the electrolytic solution is brought into contact with the imprint pattern over the shot areas, and
the electrode is brought into contact with the electrolytic solution in the shot areas collectively.

11. A manufacturing method of a semiconductor device comprising:
forming a conductive layer on a base layer;
forming an imprint pattern on the conductive layer;
bringing an electrolytic solution into contact with the imprint pattern;
bringing an electrode into contact with the electrolytic solution;
applying a voltage between the conductive layer and the electrode;
measuring a current flowing between the conductive layer and the electrode when the voltage is applied between the conductive layer and the electrode;
determining presence or absence of a defect of the imprint pattern based on a measuring result of the current; and
processing the base layer via the imprint pattern when it is determined that there is no defect of the imprint pattern.

12. The manufacturing method according to claim 11, wherein the electrolytic solution is selectively jetted onto the imprint pattern.

13. The manufacturing method according to claim 12, wherein the electrolytic solution is jetted onto each shot or part of an area in a shot.

14. The manufacturing method according to claim 13, wherein the electrolytic solution is jetted by an ink jet method.

15. The manufacturing method according to claim 11, wherein
the electrode is separated for each shot, and
the electrode is switched according to a shot to be an inspection target.

16. The manufacturing method according to claim 11, wherein
the electrolytic solution is selectively jetted onto the imprint pattern,
the electrolytic solution is jetted onto each shot or part of an area in a shot,
the electrode is separated for each shot, and
the electrode is switched according to a shot to be an inspection target.

17. The manufacturing method according to claim 11, wherein
the forming the imprint pattern on the conductive layer includes
jetting an imprint material onto the conductive layer,
pressing a template, on which a recess portion corresponding to the imprint pattern is formed, against the imprint material, and
making the imprint material to cure while pressing the template against the imprint material.

18. The manufacturing method according to claim 17, wherein one in-line inspection stage is shared by a plurality of imprint stages.

19. The manufacturing method according to claim 11, wherein
the imprint pattern is formed separately for each shot area and the electrolytic solution is brought into contact with the imprint pattern separately for each shot area, and
the electrode is brought into contact with all of electrolytic solutions in a plurality of shot areas collectively.

20. The manufacturing method according to claim 11, wherein
the imprint pattern is formed continuously over a plurality of shot areas and the electrolytic solution is brought into contact with the imprint pattern over the shot areas, and
the electrode is brought into contact with the electrolytic solution in the shot areas collectively.
